(19) United States
(12) Patent Application Publication
(10) Pub. No.: US 2009/0008794 A1
(43) Pub. Date: Jan. 8, 2009

(54) Thickness Indicators for Wafer Thinning

(76) Inventors: Weng-Jin Wu, Hsinchu City (TW); Ku-Feng Yang, Dali City (TW); Hung-Pin Chang, Taipei (TW); Wen-Chih Chiou, Miaoli (TW); Chen-Hua Yu, Hsin-Chu (TW)

Correspondence Address: SLATER & MATSIL, L.L.P., 17950 PRESTON ROAD, SUITE 1000, DALLAS, TX, 75252, US

(21) Appl. No.: 11/773,171

(22) Filed: Jul. 3, 2007

(51) Int. Cl. H01L 21/66; B24B 7/00; H01L 23/48; H01L 21/00

(52) U.S. Cl. 257/777; 438/10; 438/16; 438/459; 451/66; 257/E21.521; 257/E23.01

(57) ABSTRACT

A wafer thinning system and method are disclosed that includes grinding away substrate material from a backside of a semiconductor device. A current change is detected in a grinding device responsive to exposure of a first set of device structures through the substrate material, where the grinding is stopped in response to the detected current change. Polishing repairs the surface and continues to remove an additional amount of the substrate material. Exposure of one or more additional sets of device structures through the substrate material is monitored to determine the additional amount of substrate material to remove, where the additional sets of device structures are located in the semiconductor device at a known depth different than the first set.

### TECHNICAL FIELD

The present invention relates, in general, to semiconductor wafer thinning, and, more particularly, to thickness indicators used for assisting the wafer thinning process.

### BACKGROUND

A semiconductor wafer generally includes a first or “front” side having integrated circuits formed thereon, and a backside comprising a thickness of a semiconductor material (e.g., silicon (Si), gallium arsenide (GaAs), or the like) either in a bulk Si/semiconductor wafer or a Si/semiconductor on insulator (SOI) package. Prior to the dicing and packaging of the individual integrated circuit chips, the backside of the wafer is typically thinned to remove unwanted semiconductor material.

There are several different bonding and wafer thinning processes that are currently used depending on the type of semiconductor substrate (e.g., SOI vs. bulk Si) or on the point in the process at which via are formed (i.e., before or after bonding). When using SOI substrates, the typical procedure temporarily bonds the first wafer die to a glass layer. The backside of the SOI wafer is then usually wet etched to an etch stop layer leaving the backside substrate around 1.8 μm thick. The etched wafer die is then bonded to another wafer, after which the glass layer is removed from the first wafer die. Once the multiple layers are bonded, via are formed to establish interlayer connections.

When bulk Si is used, one method begins with a first wafer die that includes back-end-of-the-line (BEOL) connections. This first wafer die is bonded to a surface of another wafer, after which the backside substrate is thinned. Once the thinning process is completed, via are then formed to establish interlayer connections.

A second method used in bulk Si wafers forms via before the bonding process. In this method, the first wafer die not only includes the active device connections, but also has the interconnecting via formed. After bonding to another wafer, the backside thinning works to expose backside connections to the pre-fabricated via.

The backside grinding process reduces the thickness of the integrated circuit chips, allows smaller packaging, provides better stress performance in laminated packages, and provides other known benefits. Existing control methods for backside grinding typically rely on the mechanical precision of the grinding tool to control the accuracy of the final thickness of the wafer. For ultra-thin three-dimensional (3D) integrated circuit (IC) wafers, the backside may be thinned to between 20-30 μm. Such thickness requirements may risk damage to the active device layer if the mechanism to determine material thickness during the backside grinding process is not accurate.

Existing methods for controlling the mechanical backside grinding process typically use a mechanical thickness dial gauge to identify the specific width or thickness for the grinding element to leave in tact. However, because the dial gauge itself is a mechanical process, its accuracy is intrinsically limited. FIGS. 1A-1C are cross-sectional diagrams illustrating a typical wafer grinding process. In FIG. 1A, semiconductor die 10, including, among other things, bulk Si 100, through Si via (TSV) 101, and passivation layer 102, is bonded to semiconductor die 11, including, among other things, bulk Si 104 and passivation layer 103. After semiconductor dies 10 and 11 are bonded together to form stacked die 12, as illustrated in FIG. 1B, processing machine 13 applies grinding surface 105 to grind away much of bulk Si 100 from stacked die 12. The thickness dial gauge (not shown) of processing machine 13 is set to stop grinding bulk Si 100 at a desired coarse thickness, typically between 50 and 30 μm.

Because the grinding process provides such a coarse grinding mechanism, the top most layer of Si of stacked wafer 12 is typically damaged, which generally prompts additional fine polishing to finish out the processing. Chemical mechanical polishing (CMP) or the like is usually performed over the damaged surface to create a more useful planarized surface in addition to more finely thinning stacked wafer 12. FIG. 1C illustrates processing machine 13 applying polishing surface 106 to continue finely thinning and repairing the top surface of stacked wafer 12. The CMP is continued until the thickness of bulk Si 100 reaches the desired amount, typically between 30 and 20 μm. Once this desired thickness is reached, TSV 101 is usually exposed for external connection to stacked wafer 12. During the CMP process, endpoint detection (EPD) is generally needed to detect the desired endpoint of the thinning. This EPD may be implemented through a time control (i.e., conducting CMP for a specified time which, in consideration of the polishing rate, should indicate a depth that the polishing will result in after the specified time). It may also be implemented through some kind of optical metrology, including optical microscopes (OM), infrared (IR) measurement, laser detection, or similar such optical measurement systems.

The precise control to implement the accuracy of the grinding/thinning process is, therefore, limited by the accuracy of the mechanical thickness dial, followed by complicated optical verification systems. If the dial cannot sufficiently control the exact depth desired, grinding may actually cross into an active device area potentially ruining the operability of the semiconductor device.

One method that was developed to overcome the problems in the grinding portion of wafer thinning is described in U.S. Patent Publication No.: 2005/0158889 by Brouillette, et al., (hereinafter “Brouillette”). Instead of relying on a mechanical thickness dial, the thickness of the semiconductor wafer is measured using optical metrology. Specifically, IR light is directed onto the semiconductor wafer. Based on the reflective and refractive properties of the semiconductor material, the system analyzes the reflected IR light wavelengths to determine the thickness of the wafer. However, while the Brouillette method provides wafer measurement without the use of physically-limited mechanical dials, the costs of the optical equipment is generally quite high. Moreover, the grinding process is typically halted each time an IR measurement is to take place. Therefore, the grinding process is slowed decreasing the overall though-put of the manufacturing process. Further still, because the grinding process is halted to perform the measurement, care is still warranted to prevent grinding into the active layers of the wafer between measurements.

### SUMMARY OF THE INVENTION

These and other problems are generally solved or circumvented, and technical advantages are generally achieved, by preferred embodiments of the present invention which forms the means for controlling the grinding/polishing processes directly in the wafer being thinned. The wafer die is manufactured to include multiple sets of device structures, such as via, trenches, alignment marks, or the like. Each set of these structures is formed at a specific, known depth relative to the backside surface. Moreover, each set is at a different, known depth, such that a gradient depth exists across the multiple sets.

As grinding begins, sensors in the grinding elements detect changes or fluctuations in the current passing through the grinding machine. These current changes or fluctuations come from the grinding surfaces coming into contact with the various ones of the device structures. The current sensor may then signal the grinding machine to stop when the current changes by a specific amount corresponding to the grinding surface hitting a specific set of device structures.

Once the grinding process stops, the polishing may begin to repair the surface and further remove the substrate material from the backside surface. Additional monitoring of the backside surface continues during polishing to determine a pattern of device structures that are successively exposed during the polishing part of the thinning process. The exposed device structures may, therefore, also control the polishing process as well.

After thinning, the configuration of the pattern formed by the exposed device structures may also be used to inspect and determine the final thickness of the substrate. Because each of the device structures is placed at a known depth, this information may be used to determine the final thickness.

In accordance with a preferred embodiment of the present invention, a method includes grinding away substrate material from a backside of a semiconductor device. A current change is detected in a grinding device responsive to exposure of a first set of device structures through the substrate material, where the grinding is stopped in response to the detected current change. Polishing continues to remove an additional amount of the substrate material. Exposure of one or more additional sets of device structures through the substrate material is monitored to determine the additional amount of substrate material to remove, where the one or more additional sets of device structures are located in the semiconductor device at a known depth different than the first set.

In accordance with another preferred embodiment of the present invention, a stacked semiconductor device includes two or more bonded semiconductor components in a stack having an exposed backside surface of a substrate. A plurality of device structures is located within the substrate where each device structure in the plurality has a known gradient depth in relation to the exposed backside surface.

In accordance with another preferred embodiment of the present invention, a method for determining a thickness of a thinned semiconductor device includes inspecting a thinned surface of the thinned semiconductor device to detect a pattern of device structures exposed through the thinned surface. The pattern is then compared to a known gradient depth of each of the device structures in the pattern to identify the thickness of the semiconductor device.

In accordance with another preferred embodiment of the present invention, a method for thinning a semiconductor wafer includes grinding a backside surface of the semiconductor wafer to remove substrate material. The grinding is ended at a predetermined depth identified by a current change detected in the grinding machine responsive to a grinding pad contacting a first set of device structures exposed through the substrate material. The backside surface of the wafer is then polished to further remove the substrate material. The polishing ends at a desired depth also identified by one or more additional sets of device structures exposed through the substrate material. These additional sets of device structures are positioned at a known gradient depth with respect to the first set.

In accordance with another preferred embodiment of the present invention, a wafer thinning machine includes one or more grinding elements each having a replaceable coarse grinding surface and one or more polishing elements, each having a replaceable fine grinding surface. There is a platen for rotatably and selectively positioning a semiconductor wafer under either the grinding elements or the polishing elements. A current sensor, associated with the grinding elements, detects any current changes caused by interaction between the semiconductor wafer and the grinding elements.

In accordance with another preferred embodiment of the present invention, a method for manufacturing a stacked integrated circuit includes forming a first set of device structures in a first wafer die, where the first set of device structures are formed having a first known depth relative to a backside surface for the first wafer die. One or more additional sets of device structures are formed in the first wafer die, where each of the additional sets of device structures is formed having a known additional depth graded in relation to the first depth, such that each set of device structures lies at a known different depth. The first wafer die is stacked onto another wafer die, where the front side of the first wafer die is bonded to the front-side of the other wafer die. The backside surface of the first wafer die is then thinned to a thickness identified by a pattern comprising ones of the sets of device structures exposed on the backside surface by the thinning.

An advantage of a preferred embodiment of the present invention is that the coarse grinding may be accomplished with greater accuracy to the appropriate level without the physical limitations found in the mechanical thickness dial.

A further advantage of a preferred embodiment of the present invention is that after the wafer has been thinned, the pattern of device structures that have been exposed on the backside surface may be used to determine and/or verify the thickness of the thinned wafer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C are cross-sectional diagrams illustrating a typical wafer grinding process;

FIGS. 2A-2B are cross-sectional views of a stacked wafer during a wafer thinning process configured according to one embodiment of the present invention;

FIGS. 3A-3B are cross-sectional views of a wafer having a thickness indicator configured according to one embodiment of the present invention;

FIGS. 4A-4D are planar top views of successive patterns formed on a surface of a stacked wafer during a wafer thinning process configured according to one embodiment of the present invention;

FIG. 4E is planar top view of a pattern formed on a surface of a stacked wafer during a wafer thinning process configured according to one embodiment of the present invention;

FIG. 5 is a cross-sectional view of a stacked IC having a wafer thinning system configured according to one embodiment of the present invention;

FIG. 6 is a cross-sectional view of a C2W stacked wafer incorporating a wafer thinning system configured according to one embodiment of the present invention;

FIG. 7 is a diagram illustrating a wafer processing system configured according to one embodiment of the present invention;

FIG. 8 is a flowchart illustrating example steps executed to implement one embodiment of the present invention;

FIG. 9 is a flowchart illustrating example steps executed to implement one embodiment of the present invention; and

FIG. 10 is a flowchart illustrating example steps executed to implement one embodiment of the present invention.

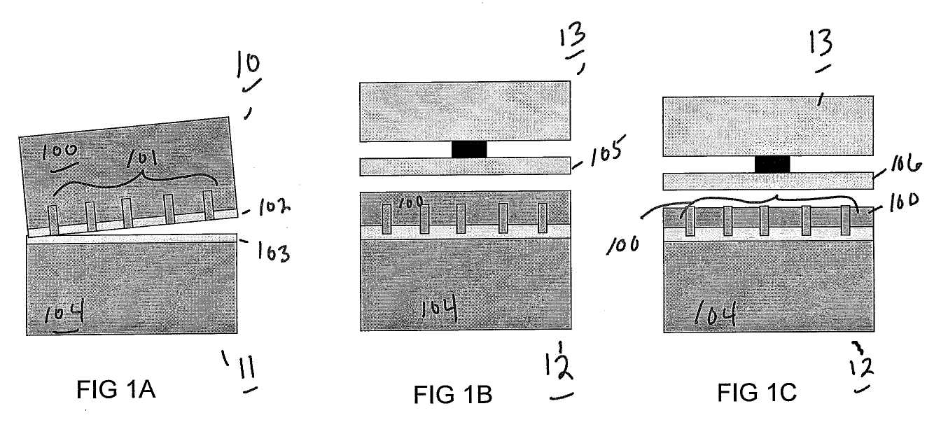

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a two-layer 3D IC semiconductor device with TSV formed as the thickness indicator. The invention may also be applied, however, to various other multilayer semiconductor devices, and the thickness indicators may be any type of device structure, such as trenches, TSV, alignment marks, combinations thereof, and the like.

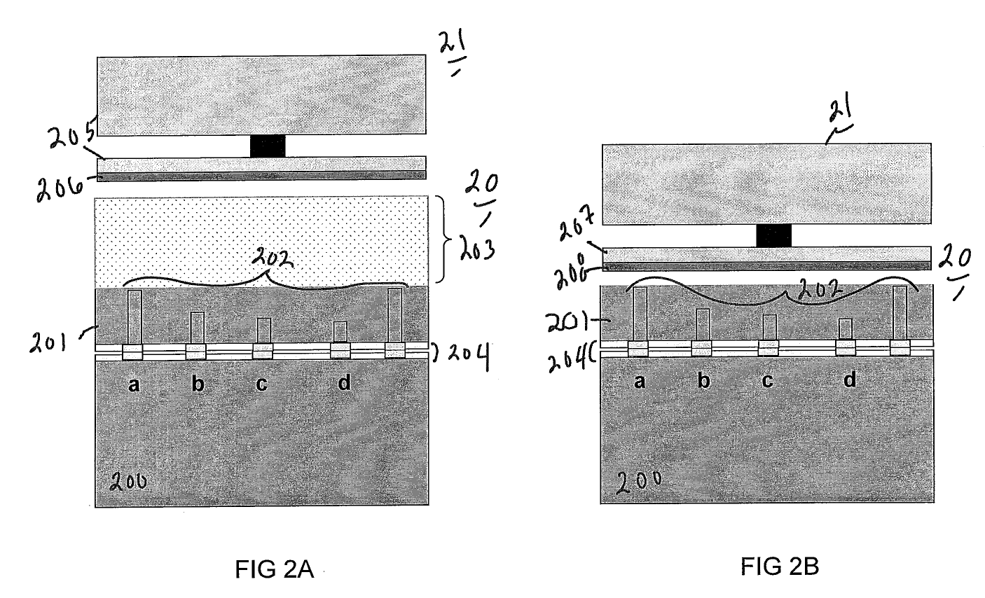

With reference now to FIG. 2A, there is shown a cross-sectional view of stacked wafer 20 during a thinning process configured according to one embodiment of the present invention. Stacked wafer 20 comprises two semiconductor dies connected at bonding layer 204 and having front-side substrate 200 and backside substrate 201. The grinding process begins with processing system 21 applying grinding surface 206 to the backside of stacked wafer 20. Processing system 21 may comprise any number of various mechanical grinding and polishing systems. Processing system 21 removes substrate amount 203 from the backside in order to leave a desired maximum grinding thickness. The backside die also comprises TSV 202 which has been formed into a pattern having varying, known specific depths. As grinding surface 206 gets close to TSV 202a, current sensor 205 detects an increase in current passing through the wheel or platen motor of processing system 21 or eddy currents that may arise during the grinding. This increase in current indicates to processing system 21 that TSV 202a is getting close. TSV 202a is known to be formed at a specific depth which represents a specific remaining thickness of substrate 201.

Eddy current is an electrical phenomenon caused when a moving (or changing) magnetic field intersects a conductor, or vice-versa. The relative motion causes a circulating flow of electrons, or current, within the conductor. These circulating eddies of current create electromagnets with magnetic fields that generally oppose the effect of the applied magnetic field. The stronger the applied magnetic field, or greater the electrical conductivity of the conductor, or greater the relative velocity of motion, the greater the currents developed and the greater the opposing field.

In the example embodiment depicted in FIG. 2A, the thickness represented by TSV 202a corresponds to the thickness at which point the grinding process is to stop. Thus, when processing system 21 detects the corresponding increased current through current sensor 205, grinding stops at the appropriate depth.

FIG. 2B is a cross-sectional view of stacked wafer 21 during a wafer thinning process configured according to one embodiment of the present invention. After coarse grinding by grinding surface 206 is complete, processing system 21 applies fine polishing surface 208 to continue removing desired portions of backside substrate 201. Processing system 21 also includes current detector 207 associated with fine polishing surface 208 in order to detect wheel or platen motor current and/or eddy current that is encountered during the polishing of stacked wafer 20. As processing system 21 removes more of backside substrate 201, fine polishing surface 208 will come into contact with more of TSV 202. In response to this contact, the wheel or platen motor current or eddy currents begin to rise. Current sensor 207 will sense this increase and signal to processing system 21 when to stop polishing to reach the desired thickness.

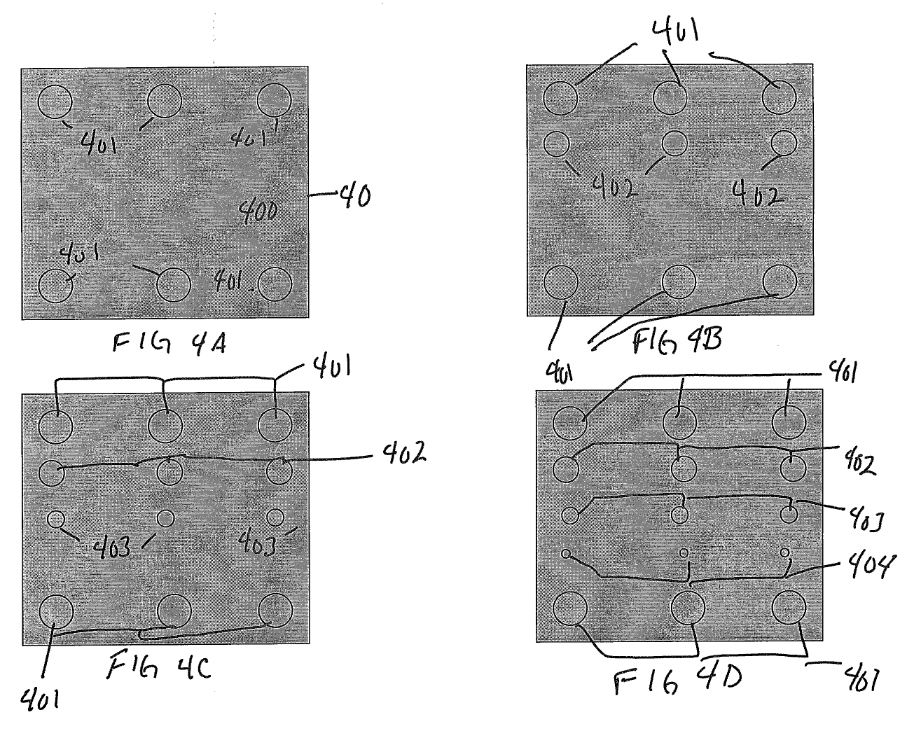

Because the TSV are formed at varying, known depths, they may also be used as a thickness indicator not only during the wafer thinning process but in the after thinning inspection (ATI) as well. For example, a desired thickness may leave enough backside substrate to keep particular TSV unexposed. The actual thickness may then be indicated through techniques such as pattern recognition, optical microscopes, scanning electron microscopes, or the like. When some TSV are exposed and others remain covered by the substrate, a pattern forms on the backside surface. (e.g., see FIG. 4) Additionally, a cross-sectional inspection of a given device will reveal the relationship between the top surface of the backside substrate and the closest TSV. As the TSV are at known depths, the thickness of the backside substrate will be easier to estimate.

It should be noted that the TSV formed for implementing the various embodiments of the present invention are accurately formed within any given wafer substrate using any known and reliable process of TSV formation. In preferred embodiments of the present invention, the TSV formed are formed to have a high depth-to-width ratio. For example, the Bosch etching process employs a deep reactive ion etching that uses two different gas types in the reactor, which can achieve etching ratios of up to around 50:1.

By providing the TSV in the systematic arrangement of known depths, the various embodiments of the present invention not only allow for determining endpoints during the thinning process but also provide assistance in ATI. ATI is the process in which the thinned wafer is inspected to determine its thickness, as well as any damage that may have occurred by the thinning process.

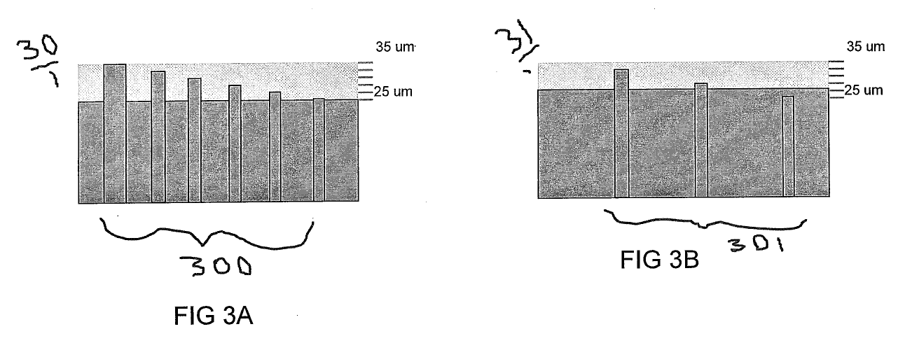

FIG. 3A is a cross-sectional view of wafer 30 having thickness indicator 300 configured according to one embodiment of the present invention. Thickness indicator 300 comprises a group of TSV formed at different specific gradient depths within wafer 30. A distance of 10 μm is illustrated (35 μm-25 μm). With six TSV making up thickness indicator 300, there is an approximate graded difference of 2 μm between the deepest and shallowest TSV. Therefore, depending on which TSV are exposed in thickness indicator 300, the thickness of the backside substrate of wafer 30 may be determined.

FIG. 3B is a cross-sectional view of wafer 31 having thickness indicator 301 configured according to one embodiment of the present invention. The embodiment represented with thickness indicator 301 illustrates that various measurement points may be provided. In wafer 31, thickness indicator 301 comprises three TSV also spanning a gradient depth of 10 μm. Therefore, an approximate difference of 5 μm exists between the deepest and shallowest TSV of thickness indicator 301.

FIGS. 4A-4D are planar top views of successive patterns formed on a surface of stacked wafer 40 during a wafer thinning process configured according to one embodiment of the present invention. In FIG. 4A, the grinding portion of the wafer thinning process has removed backside substrate 400 to reach TSV 401. The wafer thinning system according to one embodiment of the present invention has formed multiple TSV within the top die of stacked wafer 40. The current illustrated example includes four sets of graded-depth TSV. The multiple TSV are formed at known, graded depths. For purposes of the example embodiment depicted in FIGS. 4A-4D, the TSV extend from a backside substrate thickness of from 35 μm to 20 μm. TSV 401 were formed as the deepest TSV in the wafer thinning system of stacked wafer 40 in which the thickness of the backside substrate with the pattern formed in FIG. 4A is approximately 35 μm.

At 35 μm, the wafer thinning processes switches from the coarse grinding over to the finer polishing. In FIG. 4B, a new pattern has been formed as backside substrate 400 is further removed during polishing. The pattern comprises TSV 401 and TSV 402. A pattern recognition sensor (not shown) views a scanned image of the substrate surface to detect the pattern of TSV 401 and 402 and recognize that the thickness of backside substrate 400 is now at 30 μm. Because four sets of TSV make up the illustrated wafer thinning system, the difference in depth between each successive set of TSV is approximately 5 μm.

The wafer thinning process continues with polishing to repair and remove further semiconductor material, reducing the thickness of backside substrate 400 to 25 μm. This depth is recognized by a pattern recognition sensor (not shown) as comprising TSV 401-403, as shown in FIG. 4C. When this pattern is present, the thickness of wafer 40 is known to be between approximately 25 μm and 21 μm. As the wafer thinning process continues, the pattern produced by TSV 401-404, as shown in FIG. 4D, indicates that the thickness of backside substrate 400 has reached at least 20 μm. This pattern represents the lowest desired thickness of wafer 40. Accordingly, the wafer thinning process would stop as the pattern of TSV 401-404 is detected by the pattern detector.

It should be noted that various additional and/or alternative embodiments of the present invention may use processes other than a pattern detector in order to detect the progress of the wafer thinning. Optical methods, such as laser and IR systems may be used to determine the endpoint of the polishing by examination of the TSV. Additionally, current detection may also be used to monitor the thickness of the backside substrate during thinning. Current sensors, which may be shared by both grinding and polishing elements or individually associated therewith, are then used to measure the changes in current in the wheel or platen motor of the wafer thinning machine and/or the changes caused by eddy current.

It should be noted that, although FIGS. 4A-4D are shown with TSV 401-404 having varied widths or diameters, alternative and/or additional embodiments of the present invention may be fabricated using TSV of the same width or diameter. An example of such an embodiment is shown in FIG. 4E. Instead of forming the patterns with different size TSV, wafer 41 has been fabricated with TSV 405, each having the same diameter.

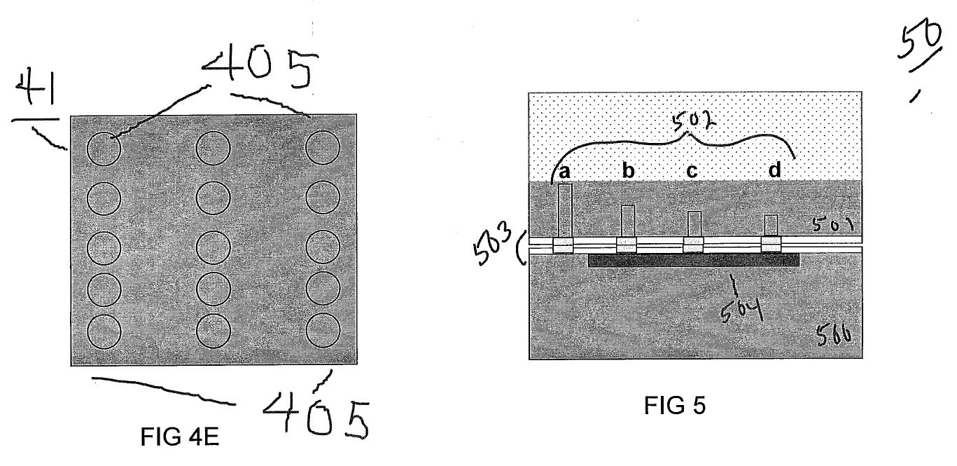

FIG. 5 is a cross-sectional view of stacked IC 50 having a wafer thinning system configured according to one embodiment of the present invention. Stacked IC 50 comprises two wafer dies joined at bonding region 503. The front-side wafer die comprises substrate 500 and active region 504, among other things. The backside wafer die includes substrate 501 and TSV 502. TSV 502 is formed at multiple, known depths that become progressively shallower from TSV 502a to TSV 502d (i.e., graded). Additionally, TSV 502b-d is connected to active region 504 while TSV 502a is not. This selective connection between TSV 502 and active device region 504 allows a more complete thickness indicator to be fabricated without a limitation based on the number of TSV to be formed for connecting active region 504. Thus, while TSV 502a is useful to designate the thickness where grinding should be replaced by polishing, it does not have to be connected into active region 504.

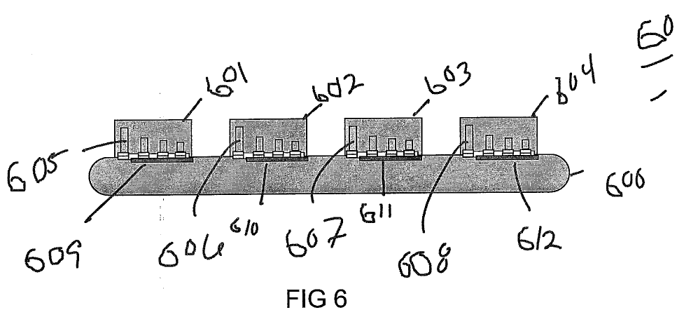

It should be noted that the various embodiments of the present invention may be used in any semiconductor device fabrication process, such as wafer-to-wafer (W2W), chip-to-wafer (C2W), chip-to-chip (C2C), and the like. FIG. 6 is a cross-sectional view of C2W stacked wafer 60 incorporating a wafer thinning system configured according to one embodiment of the present invention. Wafer 600 is processed to include active device regions 609-612. Individual IC chips 601-604 have been separately fabricated, tested, and separated. IC chips 601-604 include thickness indicator TSV 605-608, respectively. These separate IC chips 601-604 are then bonded to wafer 600 at locations corresponding to active device regions 609-612. When C2W stacked wafer 60 enters the wafer thinning process, grinding and polishing occur on the backside substrate of IC chips 601-604. A detection method detects when each of the individual TSV in thickness indicator TSV 605-608 are exposed. Once the backend substrate for each of IC chips 601-604 has been thinned to the desired level, the stacked die may be separated from C2W stacked wafer 60 for use.

It should be noted that any of the detection methods described in the various methods above may be used to detect the exposure of the individual TSV in thickness indicator TSV 605-608. Such detection methods include current monitoring (such as wheel or platen motor current and eddy current), optical pattern recognition, laser and IR measurement systems, optical microscopes (OM), scanning electron microscopes (SEM), and the like.

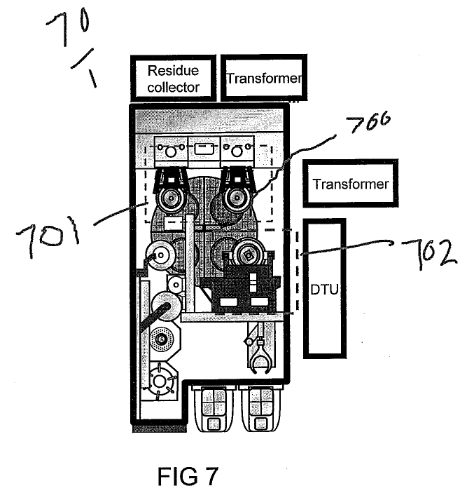

FIG. 7 is a diagram illustrating processing system 70 configured according to one embodiment of the present invention. Processing system 70 positions wafer 700 under the processing areas of processing system 70 using a wheel or platen. The first area, grinding region 701 includes replaceable grinding pads on grinding elements that have current sensors formed therein. The grinding from grinding region 701 continues until the current change is detected when the first set of device structures are reached. Device structures can be structures such as TSV, trenches, alignment marks, and the like. Wafer 700 is then rotated on the platen or wheel such that the region that was previously under grinding region 701 is now positioned under CMP region 702. CMP region 702 has polishing elements that have replaceable polishing surfaces thereon. CMP is performed on the substrate damaged by the grinding to repair and continue to remove the material from the backside of wafer 700 to reach the desired thickness. Detection features, such as those that have been disclosed herein, including additional current sensors within the polishing elements, are incorporated into CMP region 702 to detect when this desired thickness is reached.

It should be noted that the wafer thinning tool illustrated in FIG. 7 is only one example of a wafer thinning tool that may be configured according to various embodiments of the present invention. Illustration of processing system 70 is not intended to limit the implementation of the present invention in any way.

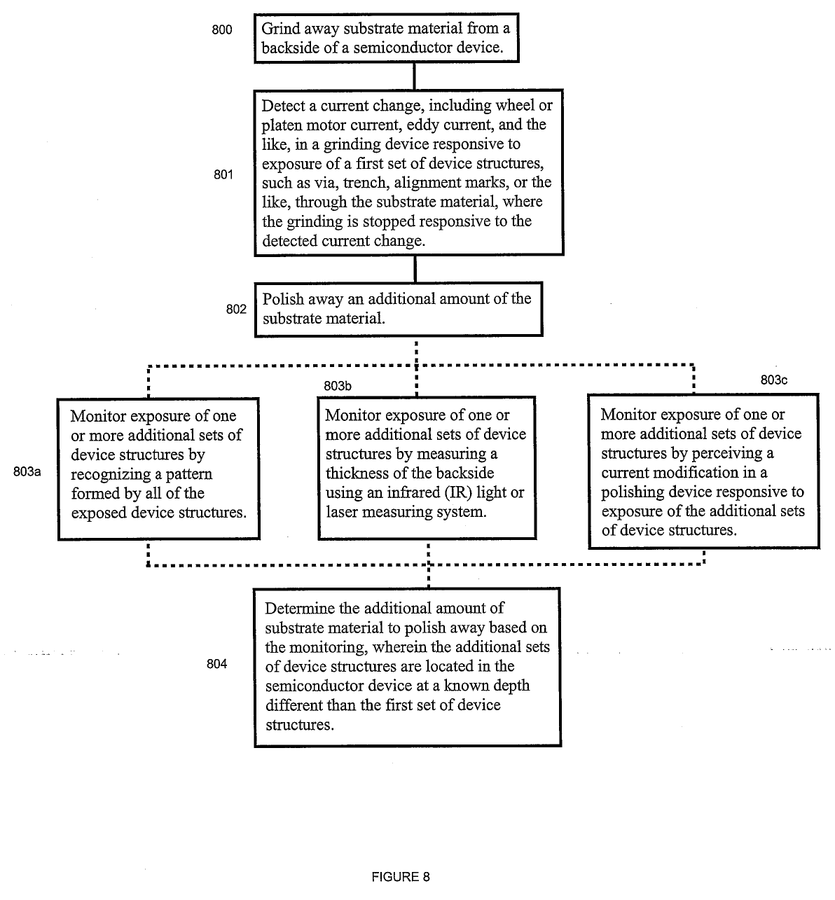

FIG. 8 is a flowchart illustrating example steps executed to implement one embodiment of the present invention. In step 800, substrate material is ground away from a backside of a semiconductor device. A current change, including wheel or platen motor current, eddy current, and the like, is detected, in step 801, within a grinding device responsive to exposure of a first set of device structures, such as via, trench, alignment marks, or the like, through the substrate material, where the grinding is stopped responsive to the detected current change. In step 802, an additional amount of the substrate material is polished away. Exposure of additional sets of device structures may be monitored by alternative means. Selected alternative methods are presented here. In alternative step 803a, exposure of one or more additional sets of device structures is monitored by recognizing a pattern formed by all of the exposed device structures. Alternatively, in step 803b, exposure of one or more additional sets of device structures is monitored by measuring a thickness of the backside using an infrared (IR) light or laser measuring system. Alternatively, in step 803c, exposure of one or more additional sets of device structures is monitored by perceiving a current modification in a polishing device responsive to exposure of the additional sets of device structures. In step 804, the additional amount of substrate material to polish away is determined based on the monitoring, where the additional sets of device structures are located in the semiconductor device at a known depth different than the first set of device structures.

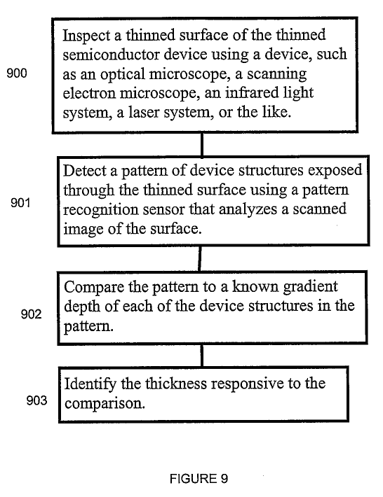

FIG. 9 is a flowchart illustrating example steps executed to implement one embodiment of the present invention. In step 900, a thinned surface of the thinned semiconductor device is inspected using a device, such as an optical microscope, a scanning electron microscope, an infrared light system, a laser system, or the like. A pattern of device structures exposed through the thinned surface is detected, in step 901, using a pattern recognition sensor that analyzes a scanned image of the surface. The pattern is compared to a known gradient depth of each of the device structures in the pattern in step 902. In step 903, the thickness is identified responsive to the comparison.

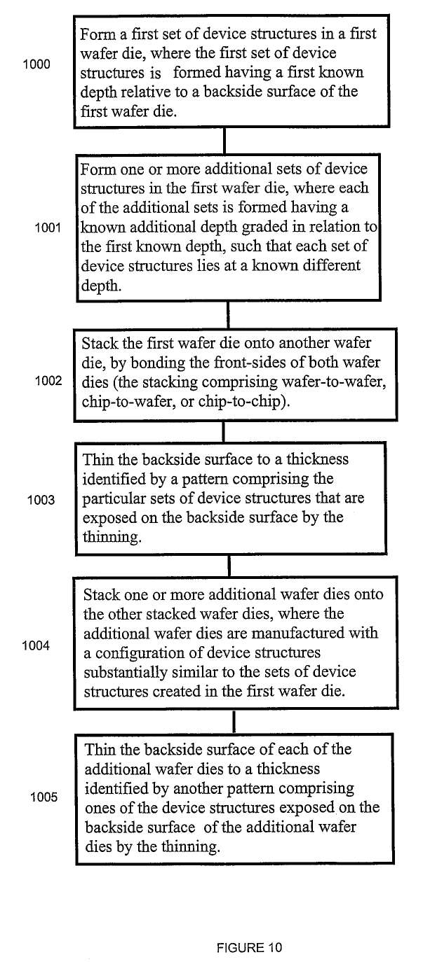

FIG. 10 is a flowchart illustrating example steps executed to implement one embodiment of the present invention. In step 1000, a first set of device structures is formed in a first wafer die having a first known depth relative to a backside surface of the first wafer die. In step 1001, one or more additional sets of device structures are formed in the first wafer die, where each of the additional sets is formed having a known additional depth graded in relation to the first known depth, such that each set of device structures lies at a known different depth. The first wafer die is stacked onto another wafer die, in step 1002, by bonding the front-sides of both wafer dies (the stacking comprising wafer-to-wafer, chip-to-wafer, or chip-to-chip). The backside surface is thinned, in step 1003, to a thickness identified by a pattern comprising the particular sets of device structures that are exposed on the backside surface by the thinning. One or more additional wafer dies are stacked onto the other stacked wafer dies, in step 1004, where the additional wafer dies are manufactured with a configuration of device structures substantially similar to the sets of device structures created in the first wafer die. The backside surface of each of the additional wafer dies is then thinned, in step 1005, to a thickness identified by another pattern comprising ones of the device structures exposed on the backside surface of the additional wafer dies by the thinning.

Although the present invention and its advantages have been described in detail, it should be understood that various changes, substitutions, and alterations can be made herein without departing from the spirit and scope of the invention as defined by the appended claims.

Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method comprising:
grinding away substrate material from a backside of a semiconductor device;
detecting a current change in a grinding device responsive to exposure of a first set of device structures through said substrate material, wherein said grinding is stopped responsive to said detected current change;
polishing away an additional amount of said substrate material; and
monitoring exposure of one or more additional sets of device structures through said substrate material to determine said additional amount, wherein said one or more additional sets of device structures are located in said semiconductor device at a known depth different than said first set.

2. The method of claim 1 wherein said current change comprises one or more of:
wheel motor current;
platen motor current; and
eddy current.

3. The method of claim 1 wherein said monitoring comprises one or more of:
recognizing a pattern formed by said exposed first set and said one or more additional sets of device structures;
measuring a thickness of said backside using an infrared (IR) light measuring system;
measuring said thickness using a laser light measuring system; and
perceiving a current modification in a polishing device responsive to exposure of said one or more additional sets of device structures.

4. The method of claim 1 wherein each device structure of said first set and said one or more additional sets of device structures comprises one or more of:
a via;
a trench; and
an alignment mark.

5. The method of claim 1 wherein said first set of device structures are not connected to an active device in said semiconductor device.

6. A stacked semiconductor device comprising:
two or more bonded semiconductor components in a stack;
an exposed backside surface of a substrate;
a plurality of device structures within said substrate having a known gradient depth in relation to said exposed backside surface.

7. The stacked semiconductor device of claim 6 wherein said stack comprises one of:
a plurality of dies on a semiconductor wafer;
one or more stacked semiconductor wafers on said semiconductor wafer; and
said plurality of dies on another plurality of dies.

8. The stacked semiconductor device of claim 6 wherein at least one of said two or more bonded semiconductor components includes one or more deep vias.

9. The stacked semiconductor device of claim 6 wherein a closest one of said plurality of device structures to said exposed backside surface identifies a stop position for grinding of said exposed backside surface.

10. The stacked semiconductor device of claim 6 wherein said furthest one of said plurality of device structures to said exposed backside surface identifies a minimum thickness of said substrate.

11. The stacked semiconductor device of claim 6 wherein each device structure of said plurality of device structures comprises one or more of:
a trench;
a via; and
an alignment mark.

12. The stacked semiconductor device of claim 6 wherein selected ones of said plurality of device structures are not connected to an active region of said stacked semiconductor device.

13. The stacked semiconductor device of claim 6 wherein said plurality of device structures are located in proximity to a scribe line.

14. The stacked semiconductor device of claim 6 further comprising:
a pattern comprising:
ones of said plurality of device structures visible in said exposed backside surface, wherein said pattern identifies a thickness of said substrate.

15. A method for determining a thickness of a thinned semiconductor device, said method comprising:
inspecting a thinned surface of said thinned semiconductor device;
detecting a pattern of device structures exposed through said thinned surface;
comparing said pattern to a known gradient depth of each of said device structures in said pattern; and
identifying said thickness responsive to said comparing.

16. The method of claim 15 wherein said inspecting comprises one of:
examining said thinned surface with an optical microscope;
examining said thinned surface with a scanning electron microscope;
examining said thinned surface using infrared light; and
examining said thinned surface using laser light.

17. The method of claim 15 wherein said detecting comprises:
optically scanning said thinned surface into a scanned image;
transmitting said scanned image to a pattern recognition sensor; and
identifying said pattern from said scanned image.

18. A method for thinning a semiconductor wafer, said method comprising:
grinding a backside surface of said semiconductor wafer to remove substrate material;
stopping said grinding at a predetermined depth, wherein said predetermined depth is identified by a current change detected in grinding machine responsive to a grinding pad contacting a first set of device structures exposed through said substrate material;
polishing said backside surface to further remove said substrate material;
stopping said polishing at a desired depth, wherein said desired depth is identified by one or more additional sets of device structures exposed through said substrate material, wherein said one or more additional sets of device structures are positioned at a known gradient depth with respect to said first set.

19. The method of claim 18 further comprising:
monitoring said one or more additional sets of device structures exposed through said substrate.

20. The method of claim 19 wherein said monitoring comprises one of:
recognizing a pattern formed by said exposed first and one or more additional sets of device structures;
detecting a current fluctuation in a polishing machine responsive to a polishing element contacting said exposed one or more additional sets of device structures;
measuring a thickness of said substrate material using an infrared light measuring system; and
measuring said thickness using a laser measuring system.

21. The method of claim 20 wherein said current change and said current fluctuation comprise one or more of:
wheel motor current;
platen motor current; and
eddy current.

22. The method of claim 18 wherein each device structure of said first and one or more additional sets of device structures comprise one or more of:
a via;
a trench; and
an alignment mark.

23. A wafer thinning machine comprising:
one or more grinding elements each having a replaceable coarse grinding surface;
one or more polishing elements, each having a replaceable fine grinding surface;
a platen for rotatably positioning a semiconductor wafer under a select one or more of said one or more grinding elements and said one or more polishing elements; and
a current sensor associated with said one or more grinding elements, wherein said current sensor detects a current change caused by interaction between said semiconductor wafer and said one or more grinding elements.

24. The wafer thinning machine of claim 23 further comprising:
an additional current sensor associated with said one or more polishing elements, wherein said additional current sensor detects current fluctuations caused by interaction between said semiconductor wafer and said one or more polishing elements.

25. The wafer thinning machine of claim 23 wherein said current sensor is also associated with said one or more polishing elements, wherein said current sensor also detects said current change caused by interaction between said semiconductor wafer and said one or more polishing elements.

26. The wafer thinning machine of claim 23 wherein said one or more polishing elements perform chemical mechanical polishing (CMP).

27. The wafer thinning machine of claim 23 further comprising:
a pattern recognition sensor associated with said one or more polishing elements, wherein said pattern recognition sensor is configured to recognize one or more patterns of device structures exposed through a surface of said semiconductor wafer.

28. The wafer thinning machine of claim 23 further comprising:
an activation switch responsive to said current sensor, wherein said activation switch automatically shuts down said one or more grinding elements responsive to signals received from said current sensor.

29. A method for manufacturing a stacked integrated circuit comprising:
forming a first set of device structures in a first wafer die, wherein said first set of device structures are formed having a first known depth relative to a backside surface for said first wafer die;
forming one or more additional sets of device structures in said first wafer die, wherein each of said one or more additional sets of device structures is formed having a known additional depth graded in relation to said first known depth, such that each set of said first set and said one or more additional sets of device structures lies at a known different depth;
stacking said first wafer die onto another wafer die, wherein a front side of said first wafer die is bonded to a front-side of said another wafer die; and
thinning said backside surface to a thickness identified by a pattern comprising ones of said first and one or more additional sets of device structures exposed on said backside surface by said thinning.

30. The method of claim 29 wherein said stacking occurs at one of:
before said first wafer die has been separated from its original wafer and before said another wafer die has been separated from its initial wafer
after said first wafer die has been separated from said original wafer and before said another wafer die has been separated from said initial wafer; and
after said first wafer die has been separated from its original wafer and after said another wafer die has been separated from said initial wafer.

31. The method of claim 29 further comprising:
stacking one or more additional wafer dies onto said stacked first and another wafer die, wherein said one or more additional wafer dies are manufactured with a configuration of device structures substantially similar to said first and one or more additional sets of device structures; and
thinning another backside surface of each of said one or more additional wafer dies to another thickness identified by another pattern comprising ones of said configuration of device structures exposed on said another backside surface by said thinning.
